(19) United States
(12) Patent Application Publication
(10) Pub. No.: US 2022/0005676 A1
(43) Pub. Date: Jan. 6, 2022

(54) CHAMBER APPLIED IN SEMICONDUCTOR PROCESS

(71) Applicant: CHANGXIN MEMORY TECHNOLOGIES, INC., Hefei City (CN)

(72) Inventor: PING-FAN CHEN, Hefei (CN)

(21) Appl. No.: 17/475,697

(22) Filed: Sep. 15, 2021

Related U.S. Application Data
(63) Continuation of application No. PCT/CN2021/082014, filed on Mar. 22, 2021.

(30) Foreign Application Priority Data
Mar. 31, 2020 (CN) 202010243117.8

(51) Int. Cl. H01J 37/32; C23C 14/56

(52) U.S. Cl. CPC H01J 37/32522; C23C 14/56

(57) ABSTRACT

This application provides a chamber applied in a semiconductor process, including a housing. The housing is closed to form a reaction cavity. A heat conduction member is disposed on an outer side wall of the housing. The heat conduction member is provided with a first surface and a second surface opposite to each other. The first surface is in contact with the outer side wall of the housing, and the second surface is configured to be in contact with an external device to form a heat conduction channel between the housing and the external device. This application has the advantages that the heat conduction member is used to establish the heat conduction channel between the housing and the external device, so that the heat conducting rate is increased, the heat in the reaction cavity can be quickly released, and the temperature in the reaction cavity can be balanced.

### CROSS-REFERENCE TO RELATED APPLICATION

This application is a continuation application of International Patent Application No. PCT/CN2021/082014, filed on Mar. 22, 2021 and entitled “Chamber Applied in Semiconductor Process”, which claims priority to Chinese patent application No. 202010243117.8, filed on Mar. 31, 2020 and entitled “Chamber Applied in Semiconductor Process”. The contents of International Patent Application No. PCT/CN2021/082014 and Chinese patent application No. 202010243117.8 are hereby incorporated by reference in their entireties.

### TECHNICAL FIELD

This application relates to the field of semiconductor manufacturing, and particularly relates to a chamber applied in a semiconductor process.

### BACKGROUND

In semiconductor manufacturing processes, many processes are completed by a deposition chamber. These manufacturing processes have certain requirements on the processing temperature. A too high or too low processing temperature may cause variation in the quality of a film on a surface of a chip. For example, a Pre clean process is mainly used to remove oxides on the surface of the chip to reduce the impedance of a contact surface. The temperature is an important control parameter for controlling the uniformity in the Pre clean process. If the temperature does not meet the requirement, the Pre clean process may not be able to completely remove the oxides on the surface of the chip, so that the impedance of the contact surface cannot be effectively reduced.

Therefore, how to balance the temperature in the deposition chamber has become an urgent problem to be solved at present.

### SUMMARY

The technical problem to be solved by this application is to provide a chamber applied in a semiconductor process, which can balance the temperature change in the chamber.

In order to solve the above problem, this application provides a chamber applied in a semiconductor process, including a housing. The housing is closed to form a reaction cavity. A heat conduction member is disposed on an outer side wall of the housing. The heat conduction member is provided with a first surface and a second surface opposite to each other. The first surface is in contact with the outer side wall of the housing, and the second surface is configured to be in contact with an external device to form a heat conduction channel between the housing and the external device.

Further, a heat conductivity coefficient of the heat conduction member is greater than a heat conductivity coefficient of the region of the housing in contact with the heat conduction member.

Further, the housing includes an upper housing and a lower housing, and the upper housing and the lower housing are closed to form the reaction cavity.

Further, the heat conduction member is disposed on an outer side wall of the lower housing.

Further, the heat conduction member surrounds the outer side wall of the housing.

Further, the heat conduction member includes first regions and a second region, and a heat conductivity coefficient of each of the first regions is less than a heat conductivity coefficient of the second region.

Further, the second region is a metal strip.

Further, the heat conduction member is provided with hollow parts, and the outer side wall of the housing is exposed through the hollow parts.

Further, the hollow parts are composed of multiple openings. The multiple openings are disposed along a circumferential direction of the housing and are spaced apart from each other. The multiple openings penetrate through the heat conduction member.

Further, a diameter of each of the multiple openings is between 5 cm and 10 cm.

Further, a distance between adjacent openings is between 2 cm and 3 cm.

Further, a thickness of the heat conduction member is between 0.2 cm and 0.3 CM.

This application has the advantages that the heat conduction member is used to establish the heat conduction channel between the housing and the external device, so that the heat conducting rate is increased, the heat in the reaction cavity can be quickly released, and the temperature in the reaction cavity can be balanced.

### BRIEF DESCRIPTION OF THE DRAWINGS

In order to more clearly illustrate the technical solutions in the embodiments of this application, the drawings required for the embodiments of this application will be briefly described below. It is apparent that the drawings in the following description are only some embodiments of this application. Those skilled in the art can also obtain other drawings according to these drawings without any creative work.

FIG. 1 is a schematic diagram of heat flow in a chamber after continuous manufacturing processes in the related art.

FIG. 2 is a schematic cross-sectional diagram of a chamber applied in a semiconductor process according to a first embodiment of this application.

FIG. 3 is a schematic three-dimensional diagram of a heat conduction member in the chamber applied in a semiconductor process according to the first embodiment of this application.

FIG. 4 is a schematic diagram of heat flow in a reaction cavity after continuous manufacturing processes of the chamber according to the first embodiment of this application.

FIG. 5 is a schematic three-dimensional diagram of a heat conduction member in a chamber applied in a semiconductor process according to a second embodiment of this application.

FIG. 6 is a schematic three-dimensional diagram of a heat conduction member in a chamber applied in a semiconductor process according to a third embodiment of this application.

FIG. 7 is a schematic three-dimensional diagram of a heat conduction member in a chamber applied in a semiconductor process according to a fourth embodiment of this application.

FIG. 8A shows temperature distribution of a chamber in the related art after continuous manufacturing processes.

FIG. 8B shows temperature distribution of the chamber according to the fourth embodiment of this application after continuous manufacturing processes.

FIG. 9 is a tendency chart of uniformity U % of a film layer on a wafer.

### DETAILED DESCRIPTION

In order to make the objectives, technical means and effects of this application clearer, this application will be further elaborated below in conjunction with the drawings. It should be understood that the embodiments described here are only a part of the embodiments of this application, rather than all of the embodiments, and are not intended to limit this application. Based on the embodiments in this application, all other embodiments obtained by those skilled in the art without creative efforts fall within the protection scope of this application.

The chamber can be applied in a Physical Vapor Deposition (PVD) process. For example, the chamber is a cavity for an Inductively Coupled Plasma (ICP).

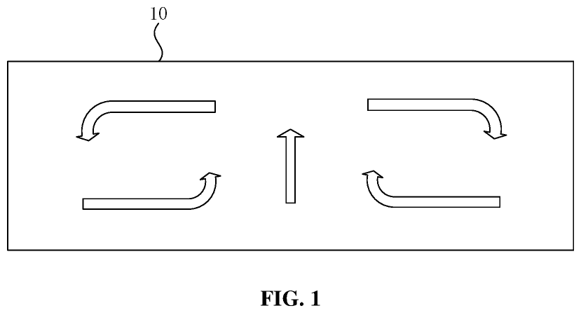

In the case of continuous multiple manufacturing processes, the plasma in the chamber will not be interrupted and will continue to heat the chamber, so that the temperature change of the chamber always tends to increase, resulting in that the temperature of the chamber cannot meet the requirements for the subsequent manufacturing processes. The applicant's research found that the reason for the above case is that the heat in the chamber cannot be dissipated in time, and the accumulation of the heat causes the temperature to continue to increase. Specifically, FIG. 1 is a schematic diagram of heat flow in a chamber after continuous multiple manufacturing processes in the related art. As the semiconductor manufacturing processes progress, most of the heat in the chamber 10 (shown by arrows in FIG. 1) can only circularly flow in the chamber and cannot be effectively released, and the accumulation of the heat in the chamber is increasing, which causes the temperature in the deposition chamber 10 to increase, so that the temperature of the chamber 10 is higher than the temperature required by the subsequent semiconductor manufacturing processes, thereby affecting the quality of the subsequent semiconductor process.

In view of the above reasons, the applicant provides a chamber applied in a semiconductor process, which can accelerate the release of the heat in the chamber, thereby preventing the temperature in the chamber from continuously increasing, and providing a good temperature basis for the subsequent manufacturing processes.

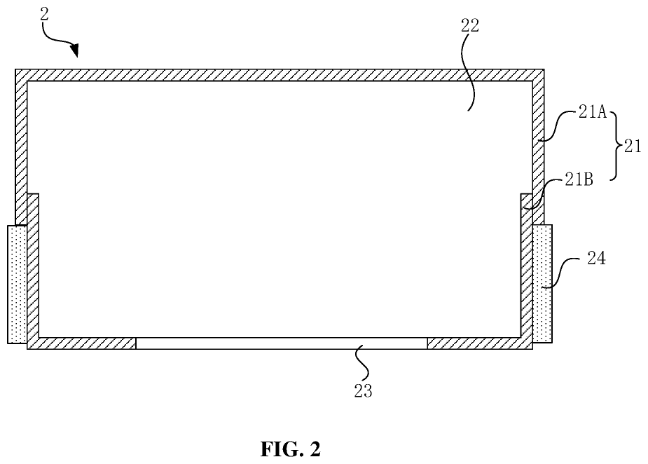

FIG. 2 is a schematic cross-sectional diagram of a chamber applied in a semiconductor process according to a first embodiment of this application. The chamber 2 includes a housing 21. The housing 21 is closed to form a reaction cavity 22. The reaction cavity 22 serves as a reaction chamber for the semiconductor process. The bottom of the housing 21 is provided with an opening 23, and a conventional device (such as a heating tray) in the semiconductor process is exposed to the reaction cavity 22 through the opening 23.

In this embodiment, the housing 21 includes an upper housing 21A and a lower housing 21B opposite to each other, and the upper housing 21A and the lower housing 21B are closed to form the reaction cavity 22. The bottom of the lower housing 21B is provided with the opening 23, and a conventional device (such as a heating tray) in the semiconductor process is exposed to the reaction cavity 22 through the opening 23.

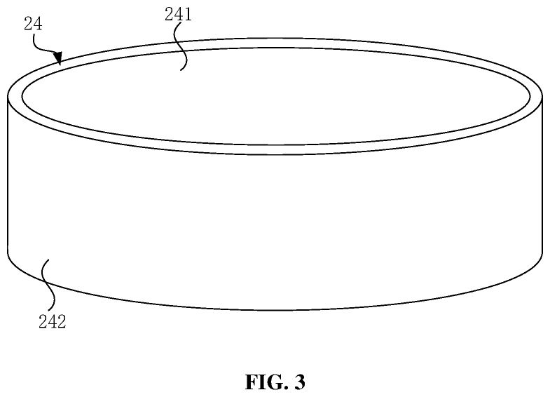

A heat conduction member 24 is disposed on an outer side wall of the housing 21. FIG. 3 is schematic three-dimensional diagram of the heat conduction member 24. The heat conduction member 24 is provided with a first surface 241 and a second surface 242 opposite to each other. The first surface 241 is in contact with the outer side wall of the housing 21, and the second surface 242 is configured to be in contact with an external device (not shown in the figure). The heat conduction member 24 forms a heat conduction channel between the housing 21 and the external device. The heat in the reaction cavity 22 is conducted to the external device through the housing 21 and the heat conduction member 24 to realize the heat dissipation of the chamber 2. The housing 21 is not in contact with the external device, there is vacuum or air between the housing 21 and the external device, the heat conduction is slow, and the heat in the chamber 2 cannot be fully released, resulting in the accumulation of the heat in the reaction cavity 22, which causes the temperature in the reaction cavity 22 to change greatly. In this application, the heat conduction member 24 is used to establish the heat conduction channel between the housing 21 and the external device, so that the heat conducting rate is increased, the heat in the reaction cavity 22 can be quickly released, and the temperature in the reaction cavity 22 can be balanced.

Further, a heat conductivity coefficient of the heat conduction member 24 is greater than a heat conductivity coefficient of the region of the housing in contact with the heat conduction member 24, so that the heat conduction member 24 can be prevented from affecting the transfer of heat, and the heat conducting rate can be further increased.

In this embodiment, the heat conduction member 24 surrounds the outer side wall of the housing 21 to establish a heat conduction channel on the circumference of the housing 21 to further increase the heat conducting rate, so that the heat in the reaction cavity 22 is fully released to avoid heat accumulation.

Further, the applicant found that a lot of heat is accumulated in a lower part of the reaction cavity 22 and is not easy to release. Therefore, in this embodiment, the heat conduction member 24 is disposed on an outer side wall of the lower housing 21B, and the heat conduction member 24 surrounds the outer side wall of the lower housing 21B, so as to accelerate the release of the heat in the lower part of the reaction cavity 22. The heat conductivity coefficient of the heat conduction member 24 may be greater than the heat conductivity coefficient of the lower housing 21B.

Further, in the first embodiment, the thickness of the heat conduction member 24 is between 0.2 cm and 0.3 cm, so that the heat conduction member 24 can be disposed between the lower housing 21B and the external device and is in contact with the lower housing 21B and the external device, so as to form the heat conduction channel.

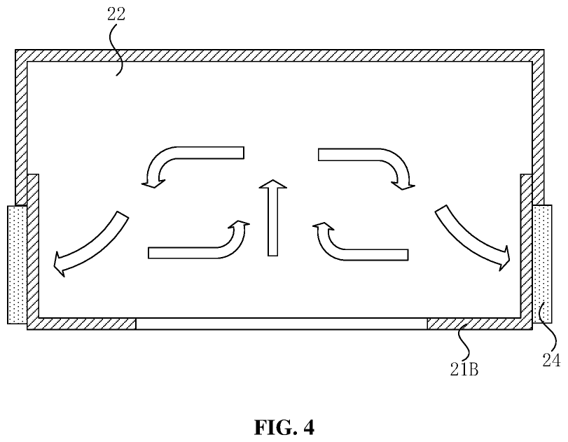

FIG. 4 is a schematic diagram of heat flow in a reaction cavity after continuous manufacturing processes of the chamber according to the first embodiment of this application. It can be seen from FIG. 4 that the heat in the reaction cavity 22 is conducted to the external device through the heat conduction channel formed by the lower housing 21B and the heat conduction member 24, thereby increasing the heat conducting rate.

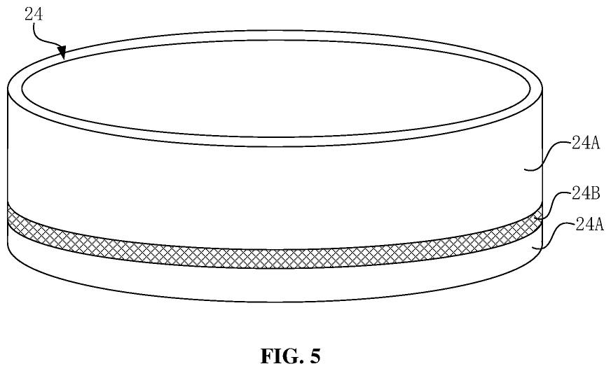

In order to further increase the heat conductivity of the heat conduction member 24, this application further provides a second embodiment. FIG. 5 is a schematic three-dimensional diagram of a heat conduction member in a chamber applied in a semiconductor process according to the second embodiment of this application. The heat conduction member 24 includes first regions 24A and a second region 24B, and the heat conductivity coefficient of each of the first regions 24A is less than the heat conductivity coefficient of the second region 24B. Each of the first regions 24A and the second region 24B may be an annular strip surrounding the outer side wall of the housing. Further, in this embodiment, one of the first regions 24A is disposed on one side of the second region 24B, and the other one of the first regions 24A is disposed on another side of the second region 24B.

In the second embodiment, the position of the second region 24B is set according to the difference in heat conductivity of different regions of the housing 21 or the difference in heat accumulation of different regions of the reaction cavity 22. For example, more heat is accumulated in the reaction cavity 22 in a region 3 cm from the bottom of the housing 21, and then the second region 24B is set corresponding to this region, so as to enhance the heat conduction of this region.

The second region 24B is a metal strip. Specifically, in the second embodiment, the second region 24B is a metal copper strip.

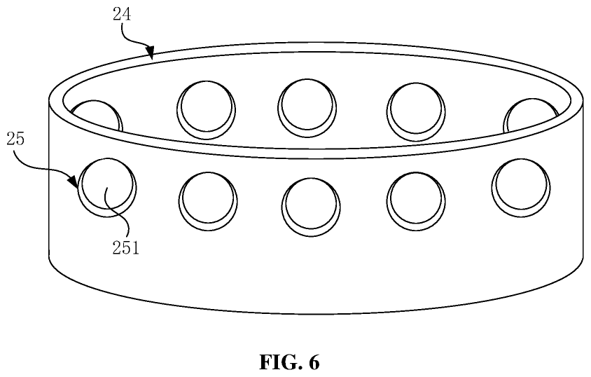

The applicant found that the heat accumulation in different regions in the reaction cavity 22 is different, some regions have more heat accumulation, and some regions have less heat accumulation. If the heat conduction member 24 is used to form a heat conduction channel in all regions, the heat conduction in different regions is the same, resulting in that the remaining heat in the region with less heat accumulation is less than the remaining heat in the region with more heat accumulation, the heat distribution in the reaction cavity 22 is uneven, and the temperature in the reaction cavity 22 is affected. Therefore, this application further provides a chamber applied in a semiconductor process according to a third embodiment. FIG. 6 is a schematic three-dimensional diagram of a heat conduction member in a chamber applied in a semiconductor process according to the third embodiment of this application. The difference between the third embodiment and the first embodiment lies in that the heat conduction member 24 is provided with hollow parts 25, and the outer side wall of the housing 21 is exposed through the hollow parts 25.

In the third embodiment, the hollow parts 25 are composed of multiple openings 251. The multiple openings 251 are disposed along a circumferential direction of the housing and are spaced apart from each other. The openings 251 penetrate through the heat conduction member 24. In other embodiments of this application, the hollow parts 25 may also be in other forms, such as belt-shaped or wave-shaped structures extending along the circumferential direction of the housing.

In the third embodiment, the positions of the hollow parts 25 are set according to the difference in heat accumulation in different regions of the reaction cavity 22. For example, less heat is accumulated in the reaction cavity 22 in a region 3 cm from the top of the housing 21, and then the hollow parts 25 are set corresponding to this region, so as to reduce the heat conduction of this region, thereby balancing the heat distribution in the reaction cavity 22 and avoiding the larger temperature change in the reaction cavity 22.

Further, in the third embodiment, the diameter of each of the openings 251 is between 5 cm and 10 cm, and the distance between adjacent openings 251 is between 2 cm and 3 cm, so that the heat conduction in the region corresponding to the hollow parts 25 can be further reduced, so as to further balance the heat distribution in the reaction cavity 22.

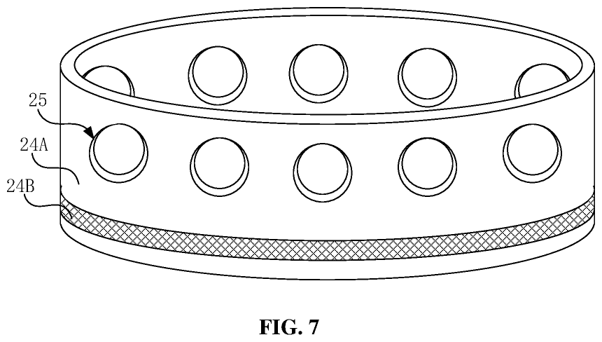

In order to further balance the heat distribution in the reaction cavity 22, this application further provides a fourth embodiment. FIG. 7 is a schematic three-dimensional diagram of a heat conduction member in a chamber applied in a semiconductor process according to the fourth embodiment of this application. Compared with the third embodiment, in the fourth embodiment, the heat conduction member 24 includes first regions 24A and a second region 24B, and the heat conductivity coefficient of each of the first regions 24A is less than the heat conductivity coefficient of the second region 24B. Each of the first regions 24A and the second region 24B may be an annular strip surrounding the outer side wall of the housing. Further, in this embodiment, one of the first regions 24A is disposed on one side of the second region 24B, and the other one of the first regions 24A is disposed on another side of the second region 24B.

In the fourth embodiment, the position of the second region 24B is set according to the difference in heat conductivity of different regions of the housing 21 or the difference in heat accumulation of different regions of the reaction cavity 22. For example, more heat is accumulated in the reaction cavity 22 in a region 3 cm from the bottom of the housing 21, and then the second region 24B is set corresponding to this region, so as to enhance the heat conduction of this region. The second region 24B is a metal strip. Specifically, in the fourth embodiment, the second region 24B is a metal copper strip.

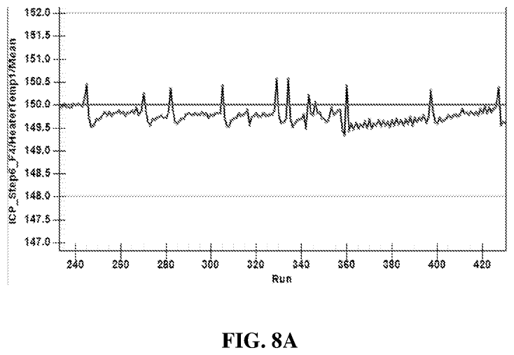

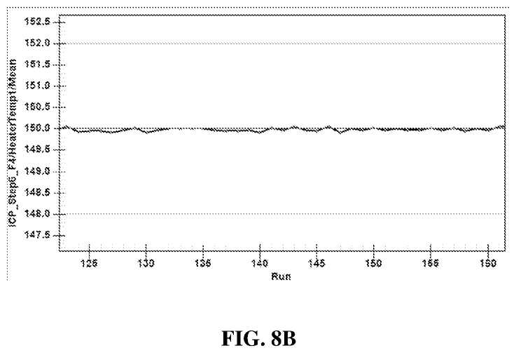

The chamber applied in a semiconductor process of this application can balance the heat distribution in the reaction cavity and avoid the larger temperature change in the reaction cavity. FIG. 8A shows temperature distribution of a chamber in the related art after continuous manufacturing processes. FIG. 8B shows temperature distribution of the chamber according to the fourth embodiment of this application after continuous manufacturing processes. It can be seen from FIG. 8A and FIG. 8B that after continuous manufacturing processes, the change of the temperature in the chamber in the related art is larger, which will greatly affect the quality of a film on a chip. However, the temperature in the chamber of this application has a little change and basically maintains the same temperature, which will not affect the quality of the film on the chip.

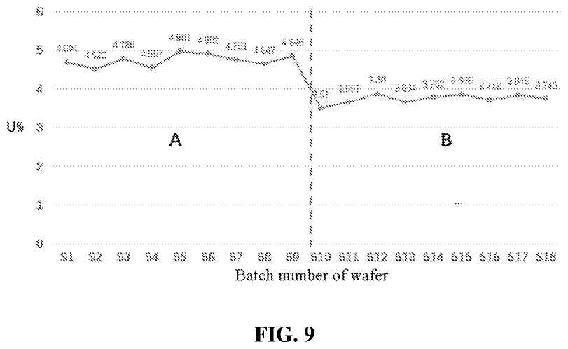

FIG. 9 is a tendency chart of uniformity U % of a film layer on a wafer. A region A is a tendency chart of uniformity U % of a film layer on a wafer obtained by the chamber in the related art. A region B is a tendency chart of uniformity U % of a film layer on a wafer obtained by the chamber of this application. Referring to FIG. 9, the uniformity U % of the film layer on the wafer obtained by the chamber in the related art is about 4.6%; and the uniformity U % of the film layer on the wafer obtained by the chamber of this application is about 3.6%, and the mean improvement is more than 1.03%.

The above is only the implementation manner of this application. It should be noted that those skilled in the art can make several improvements and modifications without departing from the principles of this application, and these improvements and modifications should also be regarded as within the protection scope of this application.

1. A chamber applied in a semiconductor process, comprising a housing, wherein the housing is closed to form a reaction cavity, a heat conduction member is disposed on an outer side wall of the housing, the heat conduction member is provided with a first surface and a second surface opposite to each other, wherein the first surface is in contact with the outer side wall of the housing, and the second surface is configured to be in contact with an external device to form a heat conduction channel between the housing and the external device.

2. The chamber applied in the semiconductor process of claim 1, wherein a heat conductivity coefficient of the heat conduction member is greater than a heat conductivity coefficient of the outer side wall of the housing in contact with the heat conduction member.

3. The chamber applied in the semiconductor process of claim 1, wherein the housing comprises an upper housing and a lower housing, and the upper housing and the lower housing are closed to form the reaction cavity.

4. The chamber applied in the semiconductor process of claim 3, wherein the heat conduction member is disposed on an outer side wall of the lower housing.

5. The chamber applied in the semiconductor process of claim 1, wherein the heat conduction member surrounds the outer side wall of the housing.

6. The chamber applied in the semiconductor process of claim 1, wherein the heat conduction member comprises first regions and a second region, and a heat conductivity coefficient of each of the first regions is less than a heat conductivity coefficient of the second region.

7. The chamber applied in the semiconductor process of claim 6, wherein the second region is a metal strip.

8. The chamber applied in the semiconductor process of claim 1, wherein the heat conduction member is provided with hollow parts, and the outer side wall of the housing is exposed through the hollow parts.

9. The chamber applied in the semiconductor process of claim 8, wherein the hollow parts are composed of multiple openings, the multiple openings are disposed along a circumferential direction of the housing and are spaced apart from each other, and the multiple openings penetrate through the heat conduction member.

10. The chamber applied in the semiconductor process of claim 9, wherein a diameter of each of the multiple openings is between 5 cm and 10 cm.

11. The chamber applied in the semiconductor process of claim 9, wherein a distance between adjacent openings is between 2 cm and 3 cm.

12. The chamber applied in the semiconductor process of claim 1, wherein a thickness of the heat conduction member is between 0.2 cm and 0.3 cm.
